(19) United States
(12) Patent Application Publication
(10) Pub. No.: US 2011/0121684 A1
(43) Pub. Date: May 26, 2011

(54) Piezoelectric Actuator

(76) Inventors: Michael Peter Cooke, Kent (GB); Martin Paul Hardy, Kent (GB); Manfred Kolkman, Messancy (BE); Christophe Tapin, La Chaussee Saint-Victor (FR)

(21) Appl. No.: 12/085,241

(22) PCT Filed: Dec. 7, 2006
(86) PCT No.: PCT/GB2006/004576

§ 371 Date: Mar. 25, 2009

(30) Foreign Application Priority Data
Dec. 8, 2005 (EP) 05257559.4

(51) Int. Cl. H01L 41/083

(52) U.S. Cl. 310/314

(57) ABSTRACT

A piezoelectric actuator comprises a stack of piezoelectric elements formed from piezoelectric material, a plurality of positive internal electrodes interdigitated with a plurality of negative internal electrodes to define active regions of the piezoelectric material which are responsive to a voltage being applied across the internal electrodes, in use. The active regions are responsive to voltage applied across the internal electrodes, in use. The piezoelectric actuator also comprises an external positive electrode for connection to the positive internal electrodes and an external negative electrode for connection to the negative internal electrodes. The stack includes an inactive stack region that defines a resistive element in the form of a coating of resistive material applied to an outer peripheral surface and/or an inner peripheral surface of the inactive stack region, wherein the resistive element is arranged to connect between the external positive electrode and the external negative electrode to allow charge to dissipate from the stack.

### TECHNICAL FIELD

The invention relates to a piezoelectric actuator comprising a plurality of piezoelectric elements arranged in a stack. In particular, but not exclusively, the invention relates to a piezoelectric actuator for use in a fuel injector of a fuel injection system of an internal combustion engine.

### BACKGROUND TO THE INVENTION

FIG. 1 is a schematic view of a piezoelectric actuator having a piezoelectric stack structure 10 formed from a plurality of piezoelectric layers or elements 12 separated by a plurality of internal electrodes 14, 16. FIG. 1 is illustrative only and in practice the stack structure 10 would include a greater number of layers and electrodes than those shown and with a much smaller spacing. The internal electrodes are divided into two groups: a positive group of electrodes (only two of which are identified at 14) and a negative group of electrodes (only two of which are identified at 16). The positive group of electrodes 14 are interdigitated with the negative group of electrodes 16, with the electrodes of the positive group connecting with a positive external electrode 18 of the actuator and the negative group of electrodes connecting with a negative external electrode (not shown) of the actuator on the opposite side of the stack 10 to the positive external electrode 18.

The positive and negative external electrodes 18 receive an applied voltage, in use, that produces an intermittent electric field between adjacent interdigitated electrodes that rapidly varies with respect to its strength. Varying the applied field causes the stack 10 to extend and contract along the direction of the applied field. Typically, the piezoelectric material from which the elements 12 are formed is a ferroelectric material such as lead zirconate titanate, also known by those skilled in the art as PZT. The actuator construction results in the presence of active regions between internal electrodes of opposite polarity. In use, when a voltage is applied across the external electrodes, the active regions are caused to expand resulting in an extension of the stack length.

The actuator is provided with an electrical connector (not shown) at the upper end of the stack (in the orientation shown) by which means the voltage is applied across the stack 10. It is known to provide the electrical connector with a “shunt” resistor, connected in parallel across the connector pins, which serves to drain the charge that accumulates within the stack 10 over a relatively long period of time, but without affecting the relatively short duration current pulses of normal operation. In other actuators a resistor is not provided in the electrical connector itself but is connected in parallel across the stack external electrodes, for example by welding or soldering, to provide the same charge drain function.

One disadvantage of having to use either of the resistors mentioned above that separate electrical connections are required to be made to the actuator circuitry, in addition to those to the external electrodes. It is also a disadvantage that the resistor cannot be connected readily to the stack 10 until relatively late on in the manufacturing process (e.g. when the connector is fitted) and so the stack 10 is either not protected during the majority of the manufacturing process or additional measures need to be applied during manufacture to protect the stack 10.

It is an object of the present invention to provide an actuator in which the aforementioned problems are alleviated or removed altogether.

### SUMMARY OF INVENTION

According to a first aspect of the present invention, there is provided a piezoelectric actuator comprising a stack of piezoelectric elements formed from a piezoelectric material, a plurality of positive internal electrodes interdigitated with a plurality of negative internal electrodes to define active regions of the material which are responsive to a voltage being applied across the internal electrodes, in use. An external positive electrode connects with the positive internal electrodes and an external negative electrode connects with the negative internal electrodes. The stack includes an inactive stack region that defines a resistive element in the form of a coating of resistive material applied to an outer peripheral surface and/or an inner peripheral surface of the inactive stack region, wherein the resistive element is arranged to connect between the external positive electrode and the external negative electrode to allow charge to dissipate from the stack.

The inactive stack region is preferably located at one or the other of the stack ends. In one particularly preferred embodiment, the end element of the piezoelectric stack, which in a conventional actuator stack is typically formed from piezoelectric material and defines an inactive stack region, defines the resistive element.

In an alternative embodiment, inactive regions of the stack may be provided at both ends of the stack.

In a further alternative embodiment, the inactive region of the stack is provided part way along the stack length so that active regions or elements of the stack are located on either side of the inactive stack region. However, it is preferable for the inactive regions to be provided at the or each end of the stack for ease of manufacture.

In one embodiment, the resistive element connects directly with both the external positive and negative electrodes (i.e. so as to itself complete the connection between the external positive and negative electrodes). Preferably, for example, the positive and negative external electrodes overlay respective sides of the stack so as to connect the respective set of internal electrodes (positive or negative) with the resistive element.

In one embodiment, a first inactive stack region is provided at one end of the stack and a second inactive stack region is provided at the other end of the stack, with each of the inactive regions being a resistive element connected between the external positive and negative electrodes.

In one embodiment, the outer peripheral surface of the inactive stack element is provided with the coating of resistive material such that the resistance path between the external electrodes extends around the outer peripheral side surface of the inactive stack region.

In another example, or in addition, an end surface of the inactive stack region is provided with the coating of resistive material so that the resistance path extends over the end surface of the stack. In this case it may also be necessary to provide a resistive coating over portions of the outer peripheral surface of the inactive stack region so as to complete the connection between each external electrode and the end surface (and, hence, to complete the connection between the external electrodes). In another embodiment, however, the positive and negative external electrodes may connect directly to the resistive coating applied to the end surface of the inactive stack region.

In one embodiment the resistive coating applied to the or each surface of the inactive stack region defines a convoluted resistance path between the positive and negative external electrodes. The convoluted resistance path may be defined by providing insulating regions over the surface which is coated so as to define an increased resistance path length between the positive and negative external electrodes.

In a preferred embodiment, the insulating regions are defined by interdigitated regions of insulating material distributed throughout the material of the resistive coating.

The inactive stack region may be a piezoelectric material from which the remainder of the stack elements are formed, the resistive coating providing the resistive path between the external electrodes. However, the inactive stack region may also be formed from other materials such as a ceramic or polymer material, for example a silicon carbide material, or a polymer stiffened with graphite or carbon fibre fillers.

In any of the embodiments of the invention an additional conductive material may be provided, in addition to the resistive element, to complete the conductive path between the positive and negative external electrodes. It is also possible to provide a resistive element which is itself an inactive element of the stack (e.g. which forms one of the tiles of the stack), but one which is also coated with the resistive coating over at least one of its surfaces.

The resistance of the resistive element is preferably at least 100 kΩ, or at least has a sufficiently high resistance value to ensure that charge is dissipated over a relatively long period of time compared with the short duration of the charge changes required in normal actuator operation (for example to initiate an injection event in a piezoelectrically actuated fuel injector). Preferably, the resistive coating that forms the resistive element is a conductive ink which can be screen printed onto selected piezoelectric elements of the stack during manufacture. Such a conductive ink confers the further benefit that it can be printed in any desired shape, for example to form convoluted resistive pathways. A further benefit is that since the resistive element is in contact with the stack over a wide area, the arrangement provides improved heat dissipation compared with known forms of shunt resistors.

Preferably, the conductive ink comprises a ruthenium compound that may be suspended in a glassy matrix. Still preferably, the conductive ink is ruthenium oxide.

According to a second aspect of the invention, there is provided a fuel injector for use in an internal combustion engine, the fuel injector including a valve which is operable to control injection of fuel into the engine under the control of an actuator, in accordance with the first aspect of the invention, by voltage and/or charge transfer across the stack. The resistance of the resistive element is selected so that charge dissipates through the resistive element over a relatively long period of time so as to not substantially affect the voltage and/or charge transfer for injection.

It will be appreciated that preferred and/or optional features of the actuator of the first aspect of the invention may be incorporated within the injector of the second aspect of the invention, alone or in appropriate combination.

### BRIEF DESCRIPTION OF DRAWINGS

The invention will now be described, by way of example only, with reference to the accompanying drawings in which;

FIG. 1 is a schematic diagram of a piezoelectric actuator known in the prior art,

FIG. 2 is a schematic diagram of a piezoelectric actuator of a first embodiment of the invention;

FIG. 3 is a schematic diagram of a piezoelectric actuator of a second embodiment of the invention;

FIG. 4 is a schematic diagram of a piezoelectric actuator of a third embodiment of the invention;

FIG. 5 is a schematic diagram of a piezoelectric actuator of a fourth embodiment of the invention, being a variant of the actuator in FIG. 3;

FIG. 6 is a schematic diagram of a piezoelectric actuator of a fifth embodiment of the invention, being a variant of the actuator in FIG. 4; and

FIG. 7 is a schematic diagram of a piezoelectric actuator of a sixth embodiment of the invention.

### DETAILED DESCRIPTION OF PREFERRED EMBODIMENTS

The piezoelectric actuator of the invention is suitable for use in a fuel injector for a compression ignition internal combustion engine. By way of example, our co-pending European patent application EP 1174615 describes a fuel injector in which a piezoelectric actuator controls movement of an injector valve needle to control the injection of fuel into the engine. Movement of the valve needle is controlled by means of voltage and/or charge transfer across a piezoelectric actuator, such as that shown in FIG. 2.

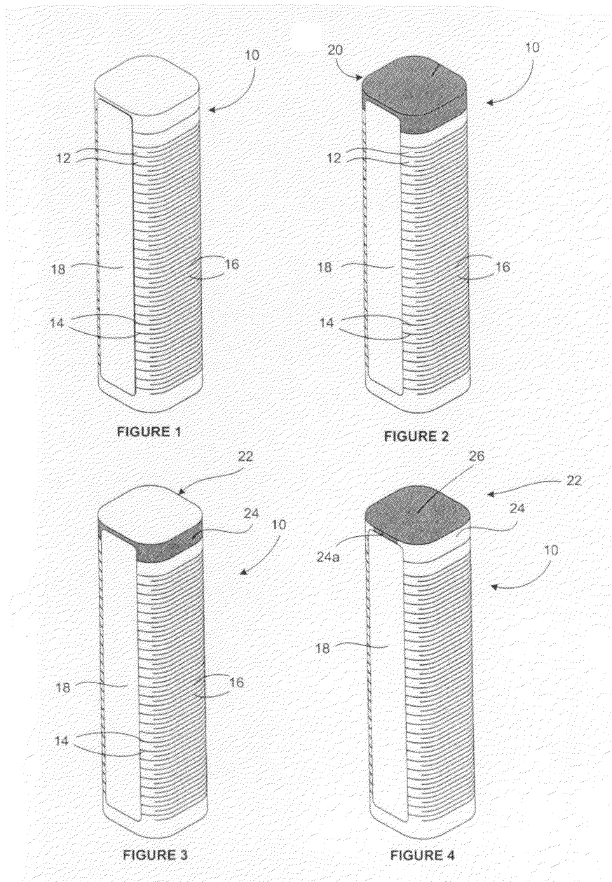

The actuator includes a plurality of active piezoelectric elements 12, also referred to as ‘layers’, which are arranged in a stack 10 and throughout which a set of negative internal electrodes 16 is interdigitated with a set of positive internal electrodes 14, as in the prior art actuator in FIG. 1. A positive external electrode 18 overlays one side of the stack 10 to connect with the positive internal electrodes 14. The positive external electrode 18 extends along the near full length of the stack 10, leaving a narrow gap of the stack exposed at each stack end. In a similar manner a negative external electrode (not shown) overlays the opposite side of the stack 10 to connect with the negative internal electrodes 16.

In use, a voltage is applied across the positive and negative internal electrodes 14, 16 that produces an intermittent electric field, between adjacent interdigitated electrodes of opposite polarity, that rapidly varies with respect to its strength. The active regions of the stack 10 between internal electrodes of opposite polarity are caused to expand, resulting in an extension of the stack length. When the voltage is removed, the stack length contracts. By controlling the voltage across the stack 10 and so varying the stack length, the valve needle of the injector is moved towards and away from a valve seat to control injection.

The stack 10 also includes an inactive region in the form of an inactive stack element or tile 20 which is located at the upper end of the stack 10 so that the upper end face of the stack is defined by a surface of the inactive element 20. The inactive element 20 takes the form of a resistive element which is formed from a material having a relatively low resistivity compared with that of the piezoelectric material of the active stack elements 12, but a relatively high resistivity compared with that of other conductors and resistive materials. The positive and negative external electrodes are of sufficient length to overlay not only the active stack elements 12, but also a part of the resistive element 20 at the upper end of the stack. The resistive element 20 therefore connects directly with the positive and negative external electrodes on each stack side and so completes a conduction path between them and, hence, between the positive and negative internal electrodes 14, 16.

Typically, the resistive element 20 has a resistance value of at least 100 kΩ so that the charge that accumulates within the stack 10 decays through the resistive element 20, from the positive external electrode 18 to the negative external electrode, over a relatively long time scale, compared with the relatively short duration of the current pulses which are necessary to provide an injection event. For example, the resistance of the resistive element 20 is typically selected to have a value that allows the charge of the stack 10 to drain over a period of a few seconds (e.g. up to 30 seconds). For an injection event (start of injection to termination of injection), voltage transfer typically occurs over a period of a fraction of a millisecond (e.g. 0.25 milliseconds) and so the presence of the resistive element 20 across the external electrodes does not have any adverse effect on the injection process.

In a conventional actuator, the inactive element at the end of the stack is typically formed from the same piezoelectric material as the active elements, or alternatively is formed from a material such as alumina. The inactive element ensures that uneven stresses caused by loads on the ends of the stack can be smoothed out before they impact the relatively fragile, active piezoelectric material. It has not previously been proposed to form the inactive element at the end of the stack from a material of high resistivity so as to provide a high resistance path across the positive and negative external electrodes to allow charge to drain from the stack 10 over a relatively long time scale. In doing so, however, the overall structure of the actuator is simplified as the requirement for a shunt resistor connected externally across the stack, or within the actuator connector pins, is avoided. As an element of the stack itself provides the high resistance charge decay path across the stack 10, it is also present throughout the whole of the manufacturing process.

In an alternative embodiment (not shown) to that in FIG. 2, an inactive element at the lower end of the stack 10 may also take the form of such a resistive element 20. By providing a resistive element at each end, each individual inactive element is able to have a higher resistance value.

Referring to FIG. 3, in another embodiment the inactive element 22 at the upper end of the stack 10 is formed from a piezoelectric material (e.g. the same material as the active stack elements 12) and is provided with a resistive coating or layer to provide the high resistance path across the positive and negative external electrodes. An outer peripheral surface 24 of the inactive element 22 is provided with the resistive coating so that the positive external electrode 18 overlays not only the positive internal electrodes throughout the stack 10 but also a portion of the resistive coating on the outer peripheral surface 24. The negative external electrode (not shown) overlays the resistive coating on the other side of the stack 10 in a similar manner. The resistive coating 24 may be formed from one of several material, for example silicon carbide, carbon, cermet, thin metal film, static dissipative polymer or rubber.

As an alternative to the upper stack element 22 being formed from a piezoelectric material, it may be formed from another material (e.g. alumina) that is suitable for smoothing out the uneven loads on the stack.

In another variation, a resistive coating may be applied to inactive regions at both the upper and lower ends of the stack 10 to provide a resistance path between the external electrodes at both stack ends.

Referring to FIG. 4, in another embodiment the upper end face 26 of the inactive element 22 is provided with the resistive coating or layer, together with portions of the outer peripheral surface 24 on each side of the stack to complete the connection to the respective external electrode. Only one of the coated portions 24a of the outer peripheral surface 24 is shown in FIG. 4. The portion 24a of the outer peripheral surface 24 that is coated on the ‘positive’ side of the stack 10 connects with the positive external electrode 18 and the portion (not shown) of the outer peripheral surface 24 that is coated on the ‘negative’ side of the stack 10 connects with the negative external electrode. The coated portions 24a of the outer peripheral surface 24 and the coated end surface 26 define a high resistance path across the external electrodes (typically in excess of 100 kΩ), so as to provide a charge drain path for the actuator over a relatively long timescale.

In both the embodiment in FIG. 3 and that in FIG. 4, the requirement to provide a portion(s) 24a of the outer peripheral surface 24 of the inactive element 22 with a resistive coating to connect with the respective external electrode will depend upon the specific external electrode configuration that is used. For example, it is not necessary to provide any portion of the outer peripheral surface 24 with a resistive coating if the external electrodes make direct contact with the coated end surface 26, either via side regions of the coating on the end surface 26 or because the external electrodes connect directly with the surface area of the upper end 26 itself.

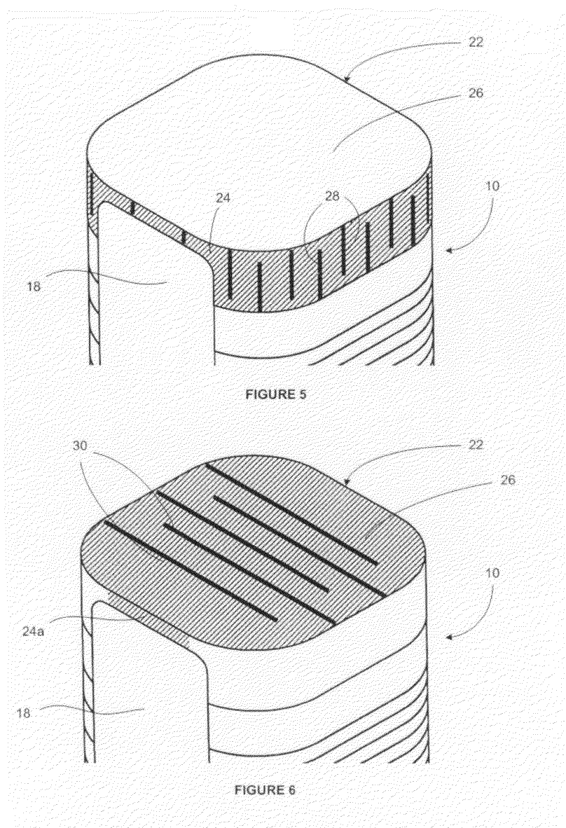

Referring to FIG. 5, in a variation of the embodiment shown in FIG. 3, the resistance of the resistive coating on the outer peripheral surface 24 can be increased by applying the coating in a pattern to define an extended resistance path length between the positive and negative external electrodes. A plurality of interdigitated insulating regions 28 extend from the upper and lower edges of the inactive element 22 to define a convoluted resistance path between the point of contact between the coating and the positive external electrode 18 on one side of the stack 10 and the point of contact between the coating and the negative external electrode (not shown) on the other side of the stack 10. As the resistance path between the external electrodes is of increased length, compared with FIG. 3, for a given coating material a higher resistance value is possible.

The embodiment in FIG. 6 utilises a similar technique to that shown in FIG. 5 to increase the resistance path length between the positive and negative external electrodes where the upper surface 26 of the element 22 is coated. In addition, interdigitated insulating regions 30 extend from opposite sides of the element 22 (i.e. from the sides in between the external electrode sides) to define a convoluted resistance path between the point of contact between the coating and the positive external electrode 18 on one side of the stack 10 and the point of contact between the coating and the negative external electrode on the other side of the stack 10. The convoluted resistance path across the end surface 26 provides an increased resistance path length between the external electrodes to provide a higher resistance value for a given coating material and thickness.

In the embodiments of FIGS. 5 and 6 the convoluted resistance path may be provided on the piezoelectric stack 10 by printing a conductive ink onto either the outer peripheral surface 24 or the end surface 26 of the inactive stack element 22 in the desired pattern. Alternatively, a resistance layer may be applied to the entire surface area of the outer peripheral surface 24 or the end surface 26 of the inactive stack element 22 and a laser may then be used to trim the resistance layer to produce the required convoluted path length. An example of a material that provides a suitable conductive ink is ruthenium oxide. Other ruthenium compounds, preferably comprised in a glassy matrix, are also suitable, for example barium ruthenate and bismuth ruthenate, although it should be appreciated that the invention is not limited to the use of the aforementioned materials.

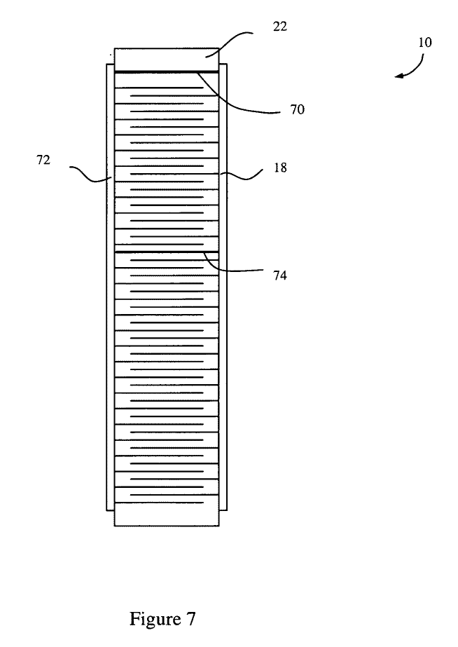

A further embodiment, as shown in FIG. 7, represents a variation on the embodiments described above which feature a resistive coating on a portion of the outer peripheral surface of the uppermost inactive element, in the orientation shown. In the embodiment of FIG. 7, the uppermost inactive element 22 carries a resistive element 70 in the form of a layer or coating on its underside surface. Put another way, the resistive layer 70 is applied to an inner peripheral surface of the inactive element 22 instead of being applied to an outer peripheral surface as in the embodiments of FIGS. 3 to 6. The resistive layer 70 extends across the entire width of the stack 10 so as to make contact with both the positive external electrode 18 and the negative external electrode 72.

In addition to including the resistive layer 70 on the inner peripheral surface of the inactive element 22, the stack 10 also includes a further resistive layer 74 positioned within the stack 10 so as to be sandwiched between two piezoelectric elements 12, which are thus rendered inactive. More than one resistive layer 74 may also be provided within the stack 10 to provide a greater number of resistive pathways, if required.

The resistive layers 70 and 74 are applied during the construction phase (or ‘green sheet phase’) of the stack 10, by screen printing the resistive coating on a surface of a piezoelectric element and laminating a further piezoelectric element on top of the resistive coating. The entire stack is then co-fired which integrates the resistive layers 70, 74 with the stack 10.

It will be appreciated that various modifications to the aforementioned embodiments are possible without departing from the scope of the invention set out in the accompanying claims. For example, in an embodiment for which the resistance path across the external electrodes is provided by a coating, as in FIGS. 3 to 6, the element 22 at the upper end of the stack 10 need not be an element that is separate from the end one of the active elements, but instead may be a stack element having both an active region (defined between internal electrodes of opposite polarity) and an inactive region, where at least a portion of the inactive region of the element is coated.

In a further alternative embodiment, the resistive element 20 or resistive coating may be incorporated part way along the length of the stack 10, rather than at one or both of the ends. In this case the regular spacing of the interdigitated internal electrodes 14, 16 is interrupted to accommodate the inactive element or region part way along the stack length. As for the previously described embodiments, either the inactive region is defined by a separate element of resistive material (e.g. as in FIG. 2) or the outer peripheral surface 24 of the inactive element or region is provided with the resistive coating (e.g. as in FIGS. 3 to 6).

Furthermore, it should be appreciated that the inventive concept encompasses a combination of the embodiments of FIGS. 3 to 6 and FIG. 7 in which case the stack 10 may include i) a resistive element formed at the upper and/or lower end of the stack 10, and/or ii) an inactive element being provided with a resistive coating on an outer peripheral surface thereof, and/or iii) a resistive layer being provided internal to the stack 10, and along the length thereof.

What is claimed is:

1. A piezoelectric actuator comprising:
a stack of piezoelectric elements formed from piezoelectric material;
a plurality of positive internal electrodes interdigitated with a plurality of negative internal electrodes to define active regions of piezoelectric material, the active regions being responsive to voltage applied across the internal electrodes, in use;
an external positive electrode for connection to the positive internal electrodes; and
an external negative electrode for connection to the negative internal electrodes;
wherein the stack includes an inactive stack region that defines a resistive element in the form of a coating of resistive material applied to an outer peripheral surface and/or an inner peripheral surface of the inactive stack region; and
wherein the resistive element is arranged to connect between the external positive electrode and the external negative electrode to allow charge to dissipate from the stack.

2. The piezoelectric actuator as claimed in claim 1, wherein the inactive stack region is located part way along the length of the stack.

3. The piezoelectric actuator as claimed in claim 1, wherein the inactive stack region is located at an end of the stack region to define a stack end surface.

4. The piezoelectric actuator as claimed in claim 1, wherein the coating of resistive material is provided over only a portion of the outer peripheral surface.

5. The piezoelectric actuator as claimed in claim 1, wherein the resistive coating defines a convoluted resistance path between the positive external electrode and the negative external electrode.

6. The piezoelectric actuator as claimed in claim 5, wherein the convoluted resistance path is defined by at least one region of insulating material distributed throughout the resistive coating.

7. The piezoelectric actuator as claimed in claim 1, wherein the inactive stack region is formed from a piezoelectric material.

8. The piezoelectric actuator as claimed in claim 1, wherein the resistive element connects directly with the external positive electrode and the external negative electrode so as to complete the connection between the positive and negative external electrodes.

9. The piezoelectric actuator as claimed in claim 1, wherein the inactive stack region is formed from a ceramic or polymer material.

10. The piezoelectric actuator as claimed in claim 9, wherein the inactive stack region is formed from a silicon carbide material.

11. The piezoelectric actuator as claimed in claim 9, wherein the inactive stack region includes a polymer stiffened with graphite or carbon fibre fillers.

12. The piezoelectric actuator as claimed in claim 1, wherein the resistance of the resistive element is at least 100 kΩ.

13. The piezoelectric actuator as claimed in claim 1, wherein the resistive coating is a conductive ink.

14. The piezoelectric actuator as claimed in claim 1, including a plurality of inactive stack regions.

15. A fuel injector for use in an internal combustion engine, the fuel injector including a valve which is operable to control injection of fuel into the engine under the control of an actuator as claimed in claim 1 by voltage and/or charge transfer across the stack, wherein the resistance of the resistive element is selected so that charge dissipates through the resistive element over a relatively long period of time so as to not substantially affect the voltage and/or charge transfer for injection.

16. A piezoelectric actuator comprising:
a stack of piezoelectric elements formed from piezoelectric material;
a plurality of positive internal electrodes interdigitated with a plurality of negative internal electrodes to define active regions of piezoelectric material, the active regions being responsive to voltage applied across the internal electrodes, in use;
an external positive electrode for connection to the positive internal electrodes; and
an external negative electrode for connection to the negative internal electrodes;
wherein the stack includes an inactive stack region located at an end of the stack region to define a stack end surface, the inactive stack region defining a resistive element in the form of a coating of resistive material applied to an outer peripheral surface and/or an inner peripheral surface of the inactive stack region;
wherein the resistive element is arranged to connect between the external positive electrode and the external negative electrode to allow charge to dissipate from the stack.
